(19) United States
(12) Patent Application Publication
(10) Pub. No.: US 2012/0285510 A1
(43) Pub. Date: Nov. 15, 2012

(54) SOLAR CELL MODULE

(75) Inventor: Rüdiger Löckenhoff, Bietigheim-Bissingen (DE)

(73) Assignee: AZUR SPACE SOLAR POWER GMBH, Heilbronn (DE)

(21) Appl. No.: 13/511,001

(22) PCT Filed: Nov. 18, 2010
(86) PCT No.: PCT/EP10/67774

§ 371 Date: Jun. 19, 2012

(30) Foreign Application Priority Data
Nov. 20, 2009 (DE) 10 2009 044 610.9

(51) Int. Cl. H01L 31/05; H01L 31/052

(52) U.S. Cl. 136/246

(57) ABSTRACT

A solar cell module having sub-units of solar cells connected in parallel, the sub-units being connected in series. To enable individual adjustment to the impinging light intensity distribution such that substantially the same photocurrent is generated in each sub-unit, the solar cells have at least first and second solar cells, which each have radiation-sensitive surfaces that are different from each other, and at least one sub-unit of the solar cell module has a first and at least one second solar cell.

The invention relates to a solar cell module, particularly to a concentrator solar module, comprising series connected subunits of parallel connected solar cells.

To convert light into electrical energy in a material saving and efficient manner using solar cells, concentrator systems are used, in which the sunlight is concentrated and deflected on solar cells having a very small area. In particular, optical systems having a large area, such as, parabolic mirrors or large Fresnel lenses are capable of generating light spots from sunlight with high optical efficiency. In these light spots, the light intensity can be many hundred times the light intensity of direct sunlight. To be able to use the light energy in concentrator solar modules with a high degree of efficiency, it is necessary that the individual solar cells are at a very small mutual separation in said modules. Otherwise, light energy would be lost unnecessarily between the solar cells. Corresponding arrangements of solar cells are therefore also referred to as densely-packed concentrator solar modules, which generally are cooled actively, for example, with water. Smaller module areas can optionally also comprise a passive cooling. So-called heat pipes can be used for cooling.

It is also known to arrange solar cells on so-called microchannel coolers which have a sandwich structure with outer layers made of ceramic, and an intermediate layer through which water flows, and which itself consists of thin, mutually connected copper foils forming a microchannel structure.

Single-step optical concentrators, such as parabolic mirrors and Fresnel lenses, generally do not generate a homogeneous light spot with sharp boundaries, but a light power distribution which decreases towards the outside. If a solar module which comprises solar cells that each have the same radiation sensitivity, that is, active area, is exposed to a light spot with inhomogeneous light power distribution, then the solar cells on the outside are exposed to less light power than those arranged in the central area, with the consequence that the outer solar cells generate less photocurrent than those located on the inside.

The solar cells in the modules are generally series connected, that is they are connected in a row. However, other arrangements are also known, which consist of subunits that comprise parallel connected solar cells, wherein the subunits themselves are series connected.

Since the current in each solar cell or subunit of a series connection is identical, the solar cells or subunits located on the outside, which generate the lowest photocurrent, consequently limit the current, so that the module works inefficiently.

From WO-A-2009/059773, a solar cell module with adapted solar cell width is known. The module comprises series connected solar cells, wherein the inside solar cells have a smaller solar radiation sensitive area than the solar cells lying outside. In spite of an inhomogeneous light irradiation, the photocurrent generated in each solar cell should thus be substantially the same. To achieve a sufficient adaptation to the different light intensities, a large number of solar cells having different active areas, i.e., radiation sensitive areas, would have to be made available. Due to the need for different tools and tool carrier replacements in automatic installations, this leads to higher costs.

The subject matter of DE-A-10 2006 015 495 is a solar cell module in which monolithically integrated solar cells are arranged via contact bridges in series which have different widths or a meandering shape.

U.S. Pat. No. 6,686,533 relates to a solar cell arrangement for a concentrator solar module. Here, a different number of cells is arranged in subgroups which are series connected to each other.

A solar cell module according to U.S. Pat. No. 4,162,174 consists of mutually abutting solar cell segments, wherein protective diodes are arranged in the marginal area of the solar cell module.

To achieve a high packing density, according to U.S. Pat. No. 4,089,705, solar cells having mutually differing geometries are connected to each other.

A solar cell module according to U.S. Pat. No. 6,225,793 comprises several mutually parallel connected bypass diodes.

The present invention is based on the problem of further developing a solar cell module, particularly a concentrator solar cell module of the type mentioned in the introduction, in such a manner that a problem-free, individual adaptation to the light intensities or the incident light intensity distribution to be considered occurs, to an extent such that substantially the same photocurrent is generated in each subunit. At the same time, it must be ensured that the solar cells can be connected without problem in the subunits. Sufficient cooling must also to be ensured.

To solve the problem, the invention essentially provides that the solar cells comprise at least first and second solar cells each having mutually differing radiation-sensitive areas, and that at least one subunit comprises at least one first and at least one second solar cell, wherein the total area of the individual sensitive areas of each subunit is dimensioned for the light intensity of the incident radiation.

According to the invention, in at least one of the subunits which are series connected to form the solar cell module, solar cells having mutually differing radiation-sensitive areas are parallel connected, so that a desired total area per subunit which is adapted to the incident light intensity can be made available.

Thus, the possibility exists, for example, in the case of a subunit comprising two solar cells, to combine two first solar cells, or a first and a second solar cell, or two second solar cells, so that in total three different radiation-sensitive total areas are available for a subunit. An additional degree of freedom is that the sequential arrangements of the solar cells within a subunit can be permuted. The result is thus a total of four combination possibilities:

Subunit a: first solar cell—first solar cell

Subunit b: first solar cell—second solar cell

Subunit c: second solar cell—first solar cell

Subunit d: second solar cell—second solar cell

Due to a targeted exploitation of the above explained degrees of freedom, the possibility exists already with two solar cell types, that is a first and a second solar cell, to achieve considerable equilibration of the photocurrents in the subunits of a large-area module. Corresponding considerations also apply if more than two solar cells having different radiation-sensitive areas are used.

In particular, it is provided that the solar cell module comprises at least three subunits, of which at least one subunit comprises exclusively first or second solar cells.

In a variant, the first solar cell differs in terms of its length, viewed in the direction of the series connection, from the second solar cell.

The possibility also exists that, viewed perpendicularly to the series connection, the width of the first and of the second solar cell is in agreement, or the width has a maximum mutual deviation of ±10%.

With regard to application technology, it is advantageous if the solar cell module comprises at least seven subunits, of which at least four subunits comprise at least one first and at least one second solar cell.

Moreover, a subunit comprising exclusively first or second solar cells is to be arranged between two subunits having at least one first and at least one second solar cell.

In particular, it is provided that the solar cell module comprises subunits having at least one first and at least one second solar cell, wherein the sequential arrangement of the at least one first and of the at least one second solar cell in the subunits differ from each other. As a result, the inhomogeneous two-dimensional intensity distribution can be taken into account.

Generally, the switching technology and the need for an active cooling result in a basic condition for the design of the subunits. In high power electronic systems utilizing active cooling, ceramic substrates having a monolayer metal coating are generally used. The metal coating is structured as the application surface of solar cells and as the conductor path. Here, the ceramic conductor plates can either be a part of a cooling body, or connected to such a cooling body.

In general, a ceramic conductor plate is used in densely packed concentrator solar modules. However, the conductor paths needed for the connection present problems, due to their high packing density.

The invention is therefore also characterized by the characteristics that the subunits are arranged on a preferably actively cooled carrier which comprises, on the solar cell side, a layer which consists of an electrically conducting material, and which is subdivided into partial area units, wherein in each case a subunit is arranged on partial area unit. As a result, the solar cells of a subunit can be parallel connected without problem. Partial area units that are connected in the sense of set theory are particularly advantageous.

The subunits themselves can be connected to each other, that is for series connection, via silver connector flags, thin gold bonds or along their electrically conducting strips which extend along their top sides, one section of which being connected to the front contacts of the solar cells of a subunit, and the other section being connected to the bottom-side contacts through the solar cells of the other subunit.

In particular, the circumferential geometry of the partial area unit is adapted to the circumferential geometry of the receiving subunit to be received.

Usually, the subunits are oriented in mutual alignment with regard to their outer longitudinal margins.

Moreover, the possibility exists that at least one partial area unit, viewed in the direction of the series connection, consists of areas or sections which extend with mutual offset, and transition into each other. The subunits are geometrically shaped accordingly.

Furthermore, the possibility exists that at least two mutually successive partial area units comprise partial areas extending with mutual offset, wherein the partial area units are oriented in such a manner with respect to each other that longitudinal margins that delimit the same sides extend with mutual offset.

If the partial area units have areas that extend with mutual offset, but no overlapping areas, then it is provided that a conductor path which is structured from the electrically conducting layer extends between the areas of the partial area unit, which are arranged with mutual offset, viewed in the direction of the series connection, and has a minimum width B where B≧0.8 mm, particularly 0.8 mm≦B≦1.2 mm, preferably B≈1 mm.

It is also provided that the electrically conducting layer, which is subdivided into partial area units is arranged on an area of the carrier, which consists of an electrically insulating material, and that, viewed in the direction of the series connection, the electrically conducting material is removed between mutually successive partial area units. As a result, the required insulation between the subunits is ensured, which can then be series connected.

The solar cells of a subunit can be connected to a number of bypass diodes which differs from the number of solar cells in the subunit. Independently thereof, it is provided that the bypass diodes, viewed in the direction of the series connection, are arranged on a side margin of the carrier, which delimits the subunits arranged in a row.

If each one of the subunits can present the same number of solar cells, then the possibility also exists for the number of solar cells of a subunit to differ from the number of solar cells of at least one additional subunit of the solar cell module.

The radiation-sensitive area of the first solar cell is preferably approximately 30-70% smaller than that of the second solar cell.

Furthermore, the separation between successive subunits should be between 50 μm and 1000 μm, in particular viewed in the direction of the series connection.

Further details, advantages and characteristics of the invention result not only from the claims, the characteristics to be taken therefrom—separately and/or in combination—, but also from the following description of preferred embodiment examples to be taken from the drawing.

The figures show:

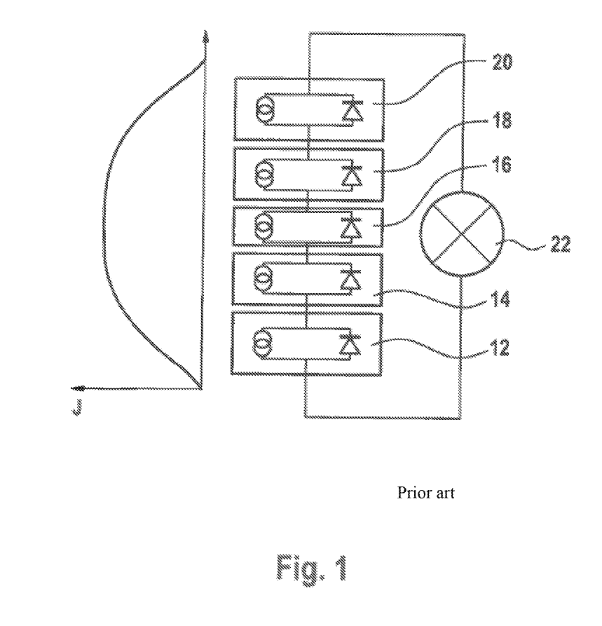

FIG. 1 a solar cell arrangement of a solar cell module according to the prior art,

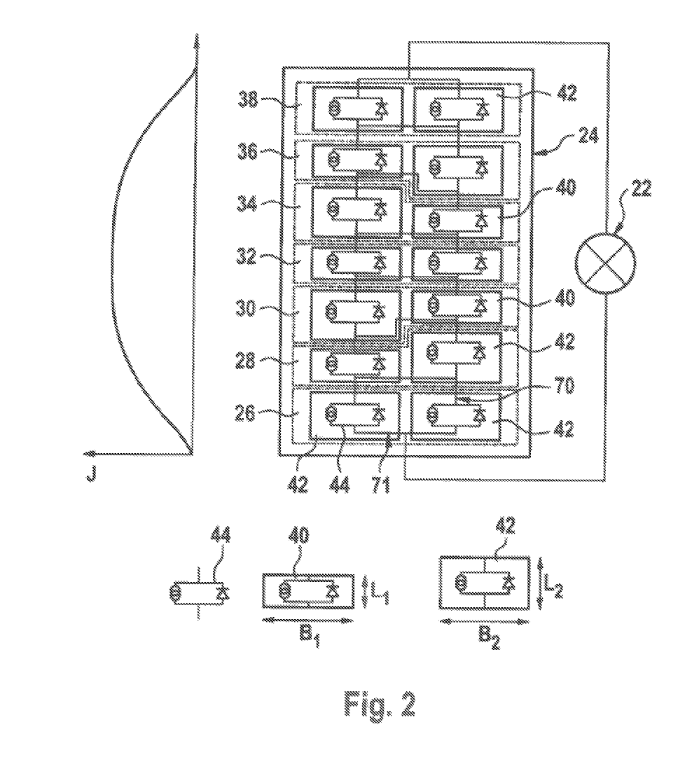

FIG. 2 a solar cell arrangement, according to the invention, of a solar cell module,

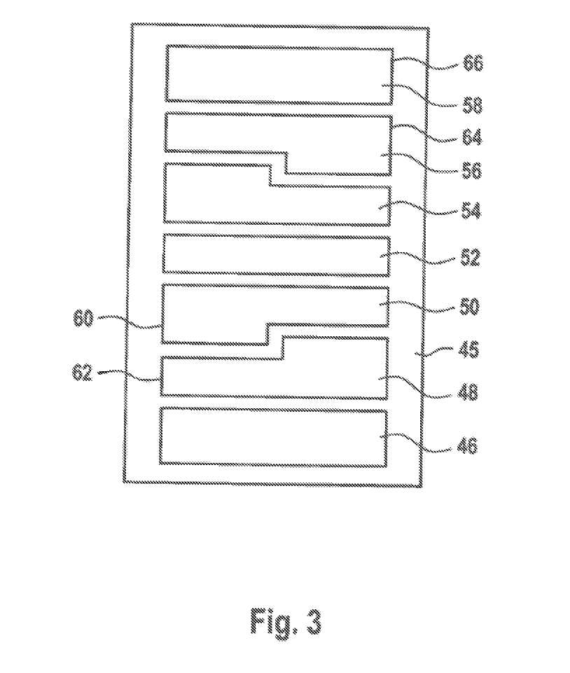

FIG. 3 a schematic diagram of an application surface arrangement of solar cell subunits according to FIG. 2,

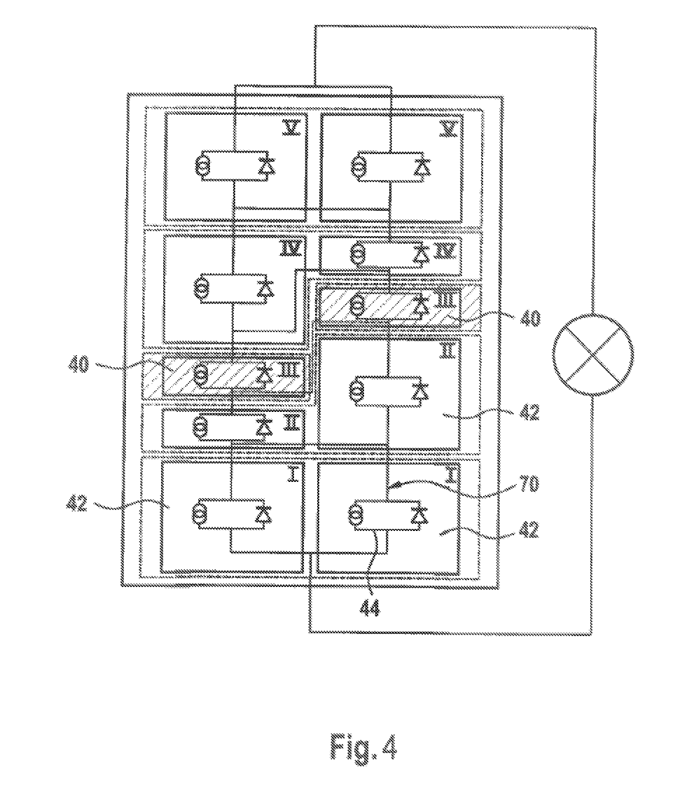

FIG. 4 an additional solar cell arrangement of a solar cell module, and

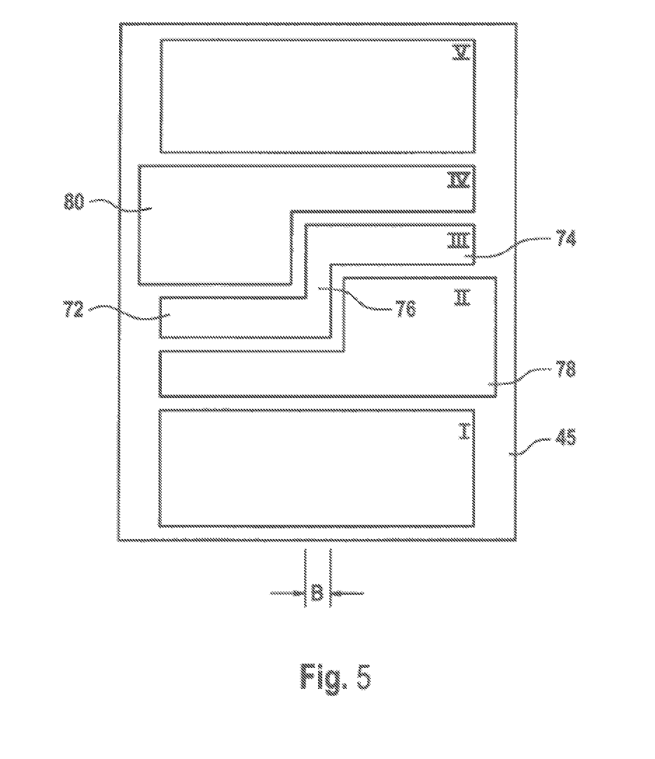

FIG. 5 an application surface arrangement of the solar cell subunits according to FIG. 4.

In FIG. 1, one can see a schematic diagram of the series connected solar cells 12, 14, 16, 18, 20 for the formation of a solar cell module according to the prior art. The series connected solar cells 12, 14, 16, 18, 20 are connected to a consumer load 22, such as, an inverter. The left portion of FIG. 1 is a schematic diagram showing a light intensity distribution in the case of concentrator systems, which acts on the solar cells 12, 14, 16, 18, 20. To achieve an adaptation of the generated photocurrents in the series connected solar cells 12, 14, 16, 18, 20, the sensitive areas, that is, the active areas of the solar cells 12, 14, 16, 18, 20, are adapted to the intensity distribution. The schematic diagram shows that the outer solar cells 12, 20 comprise a larger sensitive area than the abutting solar cells 14, 18 which again have a larger surface extent than the inner lying solar cells 16. A corresponding arrangement is also obtained generally from WO-A-2009/059773. A plurality of solar cells having different radiation-sensitive surfaces is required, as can be seen, to generate approximately the same photocurrent in each solar cell 12, 16, 16, 18, 20. Consequently, in larger modules, a plurality of solar cell designs is required, making industrial manufacture impractical.

To eliminate the disadvantages of the prior art, and to nevertheless avoid a current limitation by the solar cells which are exposed to a lower light intensity, in accordance with the light intensity distribution, the following is proposed according to the invention.

FIG. 2 is a schematic top view of a module 24 comprising the subunits 26, 28, 30, 32, 34, 36, 38 of parallel switched solar cells that are not marked in further detail. The subunits 26, 28, 30, 32, 34, 36, 38 are series connected, and connected to a consumer load, such as, an inverter 22. The subunits 26, 28, 30, 32, 34, 36, 38, with their solar cells which in each case are parallel switched, in each case make available a radiation-sensitive area which is adapted to the light intensity of the concentrator radiation, the basic course of which is reproduced in FIG. 2 on the left.

For the subunits 26, 28, 30, 32, 34, 36, 38 to be able to make available mutually differing or identical sensitive areas to the required extent, solar cells having differently sensitive areas are connected in the embodiment example; they are referred to as first and second solar cells. A schematic representation of a first solar cell 40 and of a second solar cell 42 is provided in the bottom portion of FIG. 2. One can see that the sensitive areas of the first and of the second solar cell 40, 42 differ from each other. Here, the solar cells 40, 42, viewed in the direction of the series connection 70, have mutually differing lengths L1, L2. In terms of their widths B1 or B2, the solar cells 40, 42 should be mutually in agreement or have preferably maximum differences of 10%. The symbol for the solar cells is marked with the reference numeral 44, which reproduces a combination of a current source with a diode.

As one can see in FIG. 2, the solar cell 40, 42, and thus the active area thereof, has the shape of a rectangle.

The first and second cells 40, 42 according to the invention, in the subunits 26, 28, 30, 32, 34 36, 38, are assembled in such a manner that, for each subunit 26, 28, 30, 32, 34, 36, 38, a total sensitive area is produced, which is adapted to the intensity course of the incident radiation in the area of the subunit, with the consequence that each one of the subunits 26, 28, 30, 32, 34, 36, 38 generates approximately the same photocurrent.

Thus, the outer subunits 26, 38, in whose areas the intensity is lowest, have the largest sensitive area, by having two second solar cells 42 be parallel connected. In the abutting subunits 28, 36, in which the intensity increases, the sensitive area is decreased, by having a first solar cell 40 be connected to a second solar cell 42.

The in each case interiorly adjacent subunits 30, 34 have an equal sensitive area, so that a first and second solar cell 40, 42 are also connected, but in the direction of the parallel connection 71 in the reversed sequential arrangement. As a result, the two-dimensionally inhomogeneous intensity distribution can be taken into account.

In the central area of the module 24, in which the maximum intensity occurs, the subunit 32 has the smallest sensitive area, by having two first solar cells 40 be connected.

If, in the embodiment examples, in each case two solar cells are parallel connected to a subunit 26, 28, 30, 32, 34, 36, 38, then, in practice, it is obviously possible for a much larger number of solar cells to form a subunit. Here, the possibility obviously also exists to connect more than two solar cells having mutually differing radiation-sensitive areas.

As an additional alternative or completion, to generate equal or approximately equal photocurrents in the subunits, the selection of the current classes of the solar cells to be used must be mentioned. Thus, the current classes of the solar cells arranged in the central area of the module can have a lower quality than the solar cells to be placed outside. As a result, an additional fine tuning of the photocurrents for each subunit is made possible.

The solar cells of a subunit 26, 28, 30, 32, 34, 36, 38 can be arranged on a ceramic conductor plate 45, which is the top side of a carrier designed as an active cooling unit. Said carrier can, in accordance with the prior art, have a sandwich structure with an upper and a lower ceramic plate as well as, arranged between the latter, an intermediate layer which makes available a microchannel structure and consists of thin copper foils, and through which a cooling fluid, such as water, flows.

The ceramic conductor plate 45 comprises, on the solar cell side, an electrically conducting layer, such as, a copper layer, which has been removed, for example, by etching, in the areas in which an electrical connection is to be interrupted. Preferably rectangular partial area units 46, 48, 50, 52, 54, 56, 58 remain, which, in term of area, are adapted to the subunits 26, 28, 30, 32, 34, 36, 38, or they have largely the same circumferential geometry, optionally differing in size, that is, they are slightly larger or smaller in terms of area than the subunits 26, 28, 30, 32, 34 36, 38. Conductor paths for connecting the subunits to, for example, bypass diodes, are not taken into account in this consideration.

Accordingly, a parallel switching of the first and second solar cells 40, 42 occurs in the selected configuration of each subunit, via the partial area units 46, 48, 50, 50, 52, 54, 56, 58. Thus, an exceedingly dense packing of the first and second solar cells 40, 42, or of the subunits 26, 28, 30, 32, 34, 36, 38 formed therefrom can occur on the ceramic conductor plate 45.

The electrically conducting surface which is applied to the ceramic layer, that is, the ceramic conductor plate, presents additional connections—not shown—to the partial area units 46, 48, 50, 52, 54, 56, 58, to connect each subunit 26, 28, 30, 32, 34, 36, 38 to bypass diodes that are present in the marginal area of the module, but not shown. Here, the number of bypass diodes can deviate from the number of the solar cells connected together in a subunit, in particular it can be smaller.

It can be seen in FIG. 3 that the respective longitudinal margins of the bottom area units 46, 48, 50, 52, 54, 56, 58 are arranged substantially in mutual alignment. For example, corresponding longitudinal margins are marked with 60, 62 on one side, and 64, 66 on the other side of the partial area units 46, 48, 50, 52, 54, 56, 58.

An arrangement to this effect is, however, not absolutely required, particularly if areas of solar cells to be connected to subunits are offset, viewed in the direction of the series connection 70, in such a manner that, for that reason, no direct contact occurs, that is, no overlap occurs of the corresponding rectangular partial sections which in each case incorporate an area of the subunit.

FIG. 4 is schematic representation of the subunits I, II, III, IV, V which—as in FIG. 2—comprise sensitive areas adapted in accordance to the light intensity distribution. Accordingly, a combination of the first and second solar cells 42 and 44 which comprise mutually differing sensitive areas to be connected occurs.

In FIG. 5, the partial area units associated with the subunits I, II, II, IV, V are marked accordingly.

One can see that the solar cells 40 of the subunit III are arranged with mutual offset in such a manner that they do not border on each other. However, to make a parallel connection possible nonetheless, the application surfaces for the solar cells 40 of the subunit III are arranged on areas of the partial area unit III, which are marked with the reference numerals 72, 74 in FIG. 5, wherein the areas 72, 74 are connected via a conductor path 76 which extends in the direction of the series connection 70, and which is applied onto the ceramic conductor plate 45. The width B of the conductor path 76 should be at least 0.8 mm, preferably approximately 1 mm. As a result of the associated configuration, the partial area unit III presents an S shaped geometry, wherein sections of the partial area units II and IV extend along the conductor path 76. The partial area unit III is also connected in the sense of the set theory as total set of the area 72 and 74 and of the conductor path 76. The other partial area units I, II, IV and V are also connected.

Since a minimum separation from the conductor path 76 must be maintained, the corresponding areas 78, 80 of the partial area units II, IV are offset, in the direction of the respective margin of the conductor plate 45. Thus, the longitudinal margins of the partial areas 78, 80, which are offset towards the margin, are not in alignment with the longitudinal margins of the remaining partial area units II, III, V, as clarified in FIG. 5.

1. Solar cell module (24), in particular concentrator solar cell module, comprising series connected subunits (26, 28, 30, 32, 34, 36, 38) of parallel connected solar cells (40, 42),
characterized in that
the solar cells comprise at least first and second solar cells (40, 42) comprising in each case mutually differing radiation-sensitive surfaces, and in that at least one subunit (26, 28, 30, 32, 34, 36, 38) of the solar cell module (24) comprises a first and at least one second solar cell.

2. Solar cell module according to claim 1,
characterized in that
the solar cell module (24) comprises at least three subunits (26, 28, 30, 32, 34, 36, 38), of which at least one a subunit (26, 32, 38) comprises exclusively first or second solar cells (40, 42).

3. Solar cell module according to claim 1,
characterized in that,
viewed in the direction of the series connection (70), the first solar cell (40) differs in its length from that of the second solar cell (42).

4. Solar cell module according to claim 1,
characterized in that,
viewed perpendicularly to the series connection (70), the first solar cell (40) and the second solar cell (42) are in agreement in terms of their width, or they have a maximum mutual difference of ±10%.

5. Solar cell module according to claim 1,
characterized in that
the solar cell module (24) comprises at least seven subunits (26, 28, 30, 32, 34, 36, 38), of which at least four subunits (28, 30, 34, 36) comprise at least one first and at least one second solar cell (40, 42).

6. Solar cell module according to claim 1,
characterized in that,
between two subunits (30, 34) having at least one first and at least one second solar cell (40, 42), a subunit (32) is arranged which comprises exclusively first or second solar cells.

7. Solar cell module according to claim 1,
characterized in that
the solar cell module (24) comprises subunits (28, 30, 34, 36) having at least one first and at least one second solar cell (40, 42), wherein the sequential arrangement of the at least one first and of the at least one second solar cell mutually differs.

8. Solar cell module according to claim 1,
characterized in that
the subunits (26, 28, 30, 32, 34, 36, 38) are arranged on a preferably actively cooled carrier (44) which, on the solar cell side, comprises a layer made of an electrically conducting material, which is subdivided into partial area units (46, 48, 50, 52, 54, 56, 58), wherein in each case a subunit (26, 28, 30, 32, 34, 36, 38) is connected on a connected partial area unit in an electrically conducting manner to said partial area unit.

9. Solar cell module according to claim 1,
characterized in that
at least one partial area unit comprises areas (72, 74) which extend with mutual offset in the direction of the series connection (70), and which are connected via a conductor path (82) structured from the electrically conducting material.

10. Solar cell module according to claim 1,
characterized in that
two mutually successive partial area units (48, 50) extend with mutual offset, with regard to their longitudinal margin (60, 62; 64, 66), on at least one side.

11. Solar cell module according to claim 1,
characterized in that
circumferential geometry of the partial area unit (46, 48, 50, 52, 54) is adapted to the subunit (26, 28, 30, 32, 34, 36 38) connected to said partial area unit, and in that the partial area unit and the bottom area unit comprise margins that extend substantially parallel to each other.

12. Solar cell module according to claim 1,
characterized in that
the electrically conducting layer which is divided into partial area units (46, 48, 50) is located on a carrier made of an electrically insulating material, and in that the electrically conducting material is removed between mutually successive partial area units, viewed in the direction of the series connection (70).

13. Solar cell module according to claim 1,
characterized in that
the solar cells of a subunit are connected to a number of bypass diodes which differs from the number of solar cells in the subunit.

14. Solar cell module according to claim 1,
characterized in that
the bypass diodes, viewed in the direction of the series connection (70), are arranged in a side margin of the module (24), which margin delimits the subunits (26, 28, 30, 32, 34, 36, 38) arranged in rows.

15. Solar cell module according to claim 1,
characterized in that
the partial area units (46, 48, 50, 52, 54) are arranged in mutual alignment, with regard to their respective longitudinal side (60, 62; 64, 68).

16. Solar cell module according to claim 1,
characterized in that
the number of solar cells of a subunit differs from the number of solar cells of at least one additional subunit of the solar cell module (24).

17. Solar cell module according to claim 1,
characterized in that
each subunit (26, 28, 30, 32, 34, 36, 38) comprises an identical number of solar cells (40, 42).

18. Solar cell module according to claim 1,
characterized in that
the radiation-sensitive surface of the first solar cell (40) is approximately 30-70% smaller than that of the second solar cell (42).

19. Solar cell module according to claim 1,
characterized in that
the separation between mutually successive subunits (26, 28, 30, 32, 34, 36, 38) is between 50 μm and 1000 μm, viewed in the direction of the series connection (70).

20. Solar cell module according to claim 1,
characterized in that
the solar cell module (24) comprises exclusively first and second solar cells (40, 42).
